(19) United States
(12) Patent Application Publication
(10) Pub. No.: US 2010/0127331 A1
(43) Pub. Date: May 27, 2010

(54) ASYMMETRIC METAL-OXIDE-SEMICONDUCTOR TRANSISTORS

(76) Inventors: Albert Ratnakumar, San Jose, CA (US); Jun Liu, Santa Clara, CA (US); Jeffrey Xiaoqi Tung, Milpitas, CA (US); Qi Xiang, San Jose, CA (US)

Correspondence Address: Treyz Law Group, 870 Market Street, Suite 984, San Francisco, CA, 94102, US

(21) Appl. No.: 12/324,789

(22) Filed: Nov. 26, 2008

(51) Int. Cl. H01L 29/78; G06F 17/50

(52) U.S. Cl. 257/365; 716/20; 257/E29.255

(57) ABSTRACT

Mixed gate metal-oxide-semiconductor transistors are provided. The transistors may have an asymmetric configuration that exhibits increased output resistance. Each transistor may be formed from a gate insulating layer formed on a semiconductor. The gate insulating layer may be a high-K material. Source and drain regions in the semiconductor may define a transistor gate length. The gate length may be larger than the minimum specified by semiconductor fabrication design rules. The transistor gate may be formed from first and second gate conductors with different work functions. The relative sizes of the first and gate conductors in a given transistor control the threshold voltage for the transistor. A computer-aided design tool may be used to receive a circuit design from a user. The tool may generate fabrication masks for the given design that include mixed gate transistors with threshold voltages optimized to meet circuit design criteria.

### BACKGROUND

This invention relates to transistors for integrated circuits, and more particularly, to transistors such as metal-oxide-semiconductor field effect transistors that have mixed gates and increased output resistances.

As process technology improves, it is becoming increasingly challenging to produce transistors for integrated circuits that satisfy design criteria. Advanced semiconductor fabrication techniques make it possible to produce metal-oxide-semiconductor transistors with short gate lengths. However, in devices with short gate lengths the source and drain regions can have an undesirably large impact on device behavior relative to the gate region. These undesirable short channel effects can be mitigated by using localized pocket implants.

Pocket implants help restore normal device operating characteristics to metal-oxide-semiconductor transistors with short gate lengths. For digital applications, symmetric layouts with dual pocket implants are often used.

Analog transistor performance can suffer when analog transistors are co-fabricated with digital transistors having low leakage current requirements. Dual pocket implants in the digital transistors reduce leakage current, but cause the transistors to exhibit drain currents that increase with increases in drain voltage. The dependence of drain current on drain voltage arises because the drain voltage affects the height of the drain-side pocket implant energy barrier. This effect, which is sometimes referred to as drain-induced threshold shift, can lead to degraded output resistance values.

Output resistance is a measure of the impact of changes in drain-source voltage on drain current. Ideally, drain current should be independent of drain-source voltage in saturation, resulting in high transistor gain. For analog applications in which high gain is desired, degraded output resistances are often unacceptable.

To address the shortcomings of dual pocket implants in analog transistors, conventional analog transistors are often fabricated using an asymmetric layout. With this type of approach, the drain-side pocket implant is omitted, leaving a single (asymmetric) source-side pocket implant. The length of the transistor channel is also increased, mitigating short channel effects.

Although conventional asymmetric transistors formed from pocket implants can exhibit satisfactory output resistance values, the formation of asymmetric pocket implants requires the use of an extra photolithographic mask to block the unneeded drain-side pocket implant during ion implantation operations.

It would therefore be desirable to be able to provide improved asymmetric transistor structures that exhibit increased output resistances and methods for fabricating asymmetric transistor structures.

### SUMMARY

Metal-oxide-semiconductor transistors may be provided on a semiconductor substrate. Source and drain regions for each transistor may be formed in the substrate. A gate insulator such as a high-K dielectric may be formed between the source and drain regions. The gate of each transistor may be formed from first and second gate conductors on the gate insulator.

The gate may have an associated gate length. On a given integrated circuit, the gate length may be several times larger than the minimum gate length specified by the semiconductor fabrication design rules for the process used to fabricate the given integrated circuit.

The gate of each transistor may have first and second gate conductors with different work functions. The first and second gate conductors may have first and second respective gate conductor lengths. The ratio of the first and second gate conductor lengths sets the threshold voltage for the transistor. The use of the first and second gate conductors produces an asymmetrical transistor configuration that reduces or eliminates the need for source-side pocket implants while allowing the transistors to exhibit increased output resistance. The increased output resistance helps the asymmetric transistors to produce enhanced gain for application such as analog circuits.

A computer-aided design tool may receive a circuit design from a circuit designer. The tool may analyze the design and automatically identify which transistors in the design should optimally be provided with threshold voltages of various magnitudes. Photolithographic masks designs can be generated and stored based on this analysis. The masks may be used in fabricating an integrated circuit. In the integrated circuit, the gate conductor length ratios in mixed gate transistors vary as needed to meet design criteria such as minimum switching speeds while reducing power consumption where switching speeds are not critical.

Further features of the invention, its nature and various advantages will be more apparent from the accompanying drawings and the following detailed description of the preferred embodiments.

### BRIEF DESCRIPTION OF THE DRAWINGS

FIG. 1 is a cross-sectional diagram of a conventional metal-oxide-semiconductor transistor with a source-side pocket implant.

FIG. 2 is a diagram showing the energy barrier associated with the source region in a metal-oxide-semiconductor transistor in accordance with an embodiment of the present invention.

FIG. 3 is a band diagram showing how p-type substrate energy bands are bent downwards in the presence of an n+ gate structure in accordance with an embodiment of the present invention.

FIG. 4 is a band diagram showing how p-type substrate energy bands are relatively unaffected in the presence of a p+ gate structure in accordance with an embodiment of the present invention.

FIG. 5 is a cross-sectional diagram of an illustrative n-channel metal-oxide-semiconductor transistor in accordance with an embodiment of the present invention.

FIG. 6 is a cross-sectional diagram of an illustrative p-channel metal-oxide-semiconductor transistor in accordance with an embodiment of the present invention.

FIGS. 7, 8, 9, 10, 11, 12, 13, and 14 are cross-sectional diagrams of an illustrative metal-oxide-semiconductor transistor during fabrication in accordance with an embodiment of the present invention.

FIG. 15 is a circuit diagram showing how an integrated circuit may have asymmetric transistors with different threshold voltages in accordance with an embodiment of the present invention.

FIG. 16 is a diagram of an illustrative circuit design system in accordance with an embodiment of the present invention.

FIG. 17 is a diagram of illustrative computer-aided design tools that may be used in designing an integrated circuit containing asymmetric transistors with different threshold voltages to optimize circuit performance in accordance with an embodiment of the present invention.

FIG. 18 is a flow chart of illustrative steps involved in designing and fabricating circuits with asymmetric metal-oxide-semiconductor transistors having threshold voltages chosen to optimize overall performance in accordance with an embodiment of the present invention.

FIG. 19 is a graph showing how asymmetric transistors with mixed gates may exhibit increased output resistance relative to comparably sized transistors with conventional gates in accordance with an embodiment of the present invention.

### DETAILED DESCRIPTION

The present invention relates to transistors such as metal-oxide-semiconductor transistors. The metal-oxide-semiconductor transistors may have gates that are formed from more than one type of metal. By altering the composition of the gate metal at different positions above the channel, asymmetric metal-oxide-semiconductor transistor structures can be formed. These transistors can exhibit improved values of output resistance (i.e., increased output resistances), making them suitable for applications such as analog circuits in which high gain is desired. The use of pocket implants can be reduced or eliminated, thereby simplifying processing. The ratio of the sizes of the gate metal portions of transistor gates can be varied within an integrated circuit without requiring complex process steps. This allows an integrated circuit to be formed that has asymmetric transistors with numerous different threshold voltages. Overall integrated circuit performance can be optimized by forming each individual circuit on the integrated circuit from transistors having appropriate threshold voltages.

Metal-oxide-semiconductor transistors in accordance with embodiments of the invention may be used on any suitable type of integrated circuit. Integrated circuits in which the transistors may be used include programmable logic device integrated circuits, microprocessors, logic circuits, analog circuits, application specific integrated circuits, memory, digital signal processors, analog-to-digital and digital-to-analog converter circuits, etc.

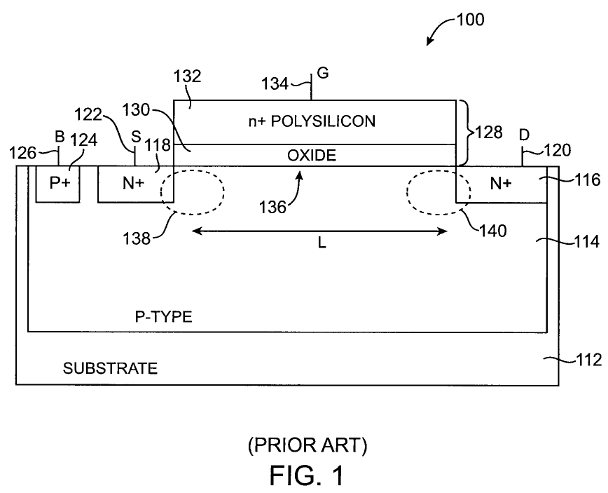

A cross-sectional view of a conventional metal-oxide-semiconductor field-effect transistor (MOSFET) is shown in FIG. 1. As shown in FIG. 1, transistor 100 may be formed from a body (well) region 114 in a silicon substrate 112. In the example of FIG. 1, transistor 100 is an n-channel metal-oxide-semiconductor (NMOS) transistor, so body region 114 is formed from silicon that has been doped p-type. P+ implant region 124 is used to form an ohmic contact between body terminal 126 of body B and the p-type silicon of body region 114.

Source S and drain D are formed on either side of gate G. Source S has an n+ implant region 118 to which source terminal 122 is connected. Drain D has an n+ implant region 116 to which drain terminal 120 is connected. Gate G has a gate terminal 134 that is electrically connected to gate structure 128. Gate structure 128 has a gate oxide layer 130 and a gate conductor 132. Gate oxide 130 is formed from silicon oxide. Gate conductor 132 may be formed from silicided doped polysilicon. In the example of FIG. 1, gate conductor 132 is formed from n+ polysilicon.

During operation of transistor 100 in a circuit, a gate voltage may be applied to gate G. If a sufficiently large positive voltage is applied to gate G, minority carriers (electrons in the NMOS transistor of FIG. 1), will form a channel in channel region 136 under gate G. Upon formation of the channel, current can flow readily between source S and drain D.

As shown in FIG. 1, transistor 10 may be characterized by a gate length L. Perpendicular to gate length L (i.e., into the page of FIG. 1), transistor 100 has an associated gate width W (typically larger than length L).

It is often advantageous to form transistors with gate lengths L that are as short as possible. Transistors with short gate lengths may be packed more densely on an integrated circuit, which allows logic designers to design more complex circuit and tends to reduce device costs. Smaller transistors may also exhibit faster switching speeds, which helps to improve circuit performance. However, use of short gate lengths such as gates that have lengths L less than about one micron can lead to nonideal transistor behavior. For example, transistors with short gate lengths may be subject to an increased risk of punchthrough. Short gate lengths can also lead to undesirably large amounts of power consumption due to increased leakage currents.

To address short channel effects such as increased punchthrough risk, it may be advantageous to provide a metal-oxide-semiconductor transistor with advanced doping profiles. For example, pocket implants may be formed in regions near the source and drain regions such as regions 138 and 140 in FIG. 1 to help prevent undesired incursions into the channel region. Pocket implants may be formed by ion implantation. The doping type of the pocket implants is opposite to that of the doping type of adjoining source-drain regions. For example, in a transistor with n-type source-drain regions, the pocket implants are p-type.

Pocket implants create energy barriers at the source and drain. In transistors used for digital logic applications, the energy barriers produced by the pocket implants help prevent punchthrough. However, symmetric designs in which pocket implants are used at both the source and drain can create problems for transistors that are used in analog applications in which high gain is desirable. This is because the magnitude of the energy barrier that is produced by the drain-side pocket implant is affected by the magnitude of the drain voltage. As the drain voltage increases, the height of the drain-side barrier is reduced, even after saturation. As a result, drain current increases with increasing drain voltage, degrading output resistance and thereby reducing gain.

To address this problem, conventional transistors such as transistor 100 may omit the drain-side pocket implant in region 140. The source-side pocket implant in region 138 may be retained to ensure that transistor 100 exhibits a suitable threshold voltage.

Eliminating the drain-side pocket implant from region 140 in conventional transistors requires the use of an additional photolithographic mask. This is because blocking structures must be formed on the surface of the semiconductor wafer during fabrication to block the implantation of dopant into region 140 while the source-side pocket implant of region 138 is being formed.

In accordance with an embodiment of the present invention, the need for pocket implants may be reduced or eliminated by forming gates from more than one conductive material. The gate conductors in a given gate structure may each have a different work function. This allows formation of an energy barrier similar to the energy barrier formed with conventional source-side pocket implants, without the need to form the pocket implants. Asymmetric transistors may therefore be created that have higher output resistances and improved gains, while reducing or eliminating pocket implant requirements.

The gate conductors in the gate may be semiconductors such as polysilicon of different doping types or metals with different electrical characteristics (as examples). The gate materials in a given transistor are formed at different lateral locations along the channel region of the transistor (i.e., at different locations within the transistor gate structure in the plane of the substrate surface).

With one suitable arrangement, which is sometimes described herein as an example, the gate structure of each transistor is mixed in that it is formed from multiple metals, each of which has a different work function. Over the portion of the channel region that would conventionally contain a source-side pocket implant, the gate may be formed from a metal with a relatively high work function. In an n-channel metal-oxide-semiconductor transistor, this metal may, for example, have a work function of about 5.1 eV, which makes its electrical performance comparable to that of a heavily doped p-type gate conductor such as a p+ polysilicon gate conductor. Over the remaining portion of the channel region in the p-channel transistor, the gate may be formed from a metal that has a relatively low work function. This portion of the gate may, for example, have a work function of about 4.2 eV, which makes its electrical performance comparable to that of a heavily doped n-type gate conductor such as an n+ polysilicon gate conductor. Other arrangements may also be used such as arrangements in which the metal work functions for different gate conductors differ by different amounts (e.g., by less than 0.3 eV, by 0.3 eV or more, by at least 0.6 eV, by at least 0.9 eV, etc.). PMOS transistors may also be formed that include mixed gates.

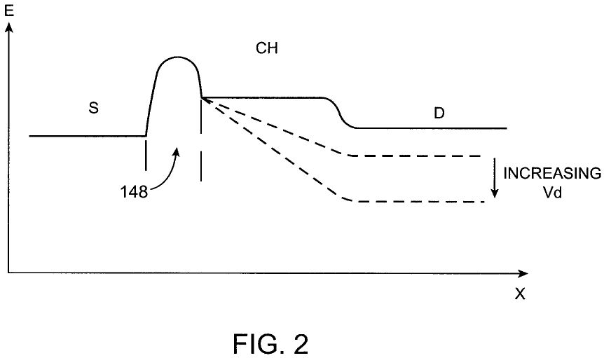

A transistor in which the source-side portion of the gate is formed from a different types of metal than the rest of the gate may have an energy band diagram structure similar to that of a conventional transistor having a source-side pocket implant. In particular, a multiconductor gate transistor in accordance with an embodiment of the invention may have a band diagram of the type shown in FIG. 2. In the example of FIG. 2, the band diagram for the transistor has been taken through source S, channel CH, and drain D. As shown in FIG. 2, there is a source-side energy barrier 148. Energy barrier 148 is present both when the transistor is unpowered (drain voltage Vd is at a ground voltage such as 0 volts) and when the transistor is powered (drain voltage Vd is at a positive power supply voltage Vdd such as 1.0 volts). Energy barrier 148 is produced by including two different gate conductors in the gate structure of the transistor that have different work functions.

The gate conductors in the gate structure may be formed at different lateral locations along the channel length. The source-side portion of the gate structure may be formed from a first gate conductor. The rest of the gate structure may be formed from a second gate conductor. The first and second gate conductors may be formed from any suitable metal materials including elemental metals, metal alloys, and other metal-containing compounds such as metal silicides, metal nitrides, etc. With one suitable arrangement, which is sometimes described herein as an example, the gate conductors are formed from metal (i.e., pure elemental metal or metal alloys). Examples of metals with lower work functions that may be used as gate conductors include aluminum and tantalum. Examples of metals with higher work functions that may be used as gate conductors include gold and tungsten. These are merely examples. Any suitable conductive materials may be used as gate conductors if desired.

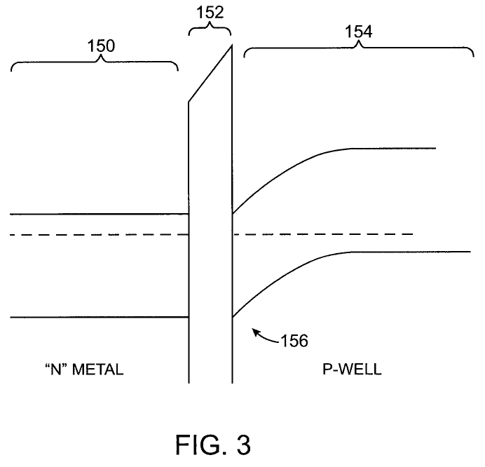

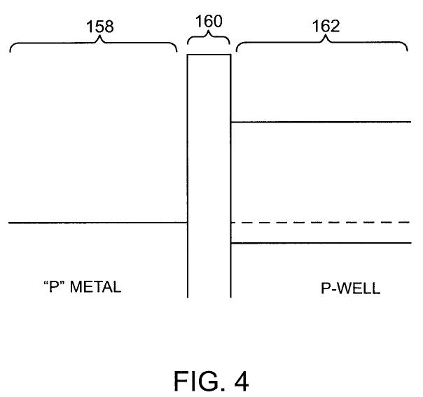

The formation of energy barrier 148 in a transistor using gate conductors with different work functions may be understood by reference to FIGS. 3 and 4.

The energy band diagram of FIG. 3 corresponds to a transistor structure in which the gate conductor has been formed from a metal or other material that has an n-type characteristic. Region 150 corresponds to this gate conductor and is shown for illustrative purposes as having a Fermi level appropriate for n+ silicon. Region 152 corresponds to the gate insulator. Region 154 corresponds to p-type silicon in the transistor's body. In equilibrium, the bands of region 154 may bend downwards as shown in FIG. 3, creating a depleted region 156 near the interface between p-type region 154 and gate insulator 152. This depletion region makes it easier to create an inversion layer under the gate insulator (i.e., in the channel region of the transistor). The presence of depletion layer 156 in transistor gate arrangements in which the gate conductor is formed from n+ semiconductor or a conductive material such as a metal with an equivalent work function (e.g., a work function of 4.2 eV), is therefore indicative of a lowered conduction band and a lowered transistor threshold voltage Vt. When relatively more of this gate conductor is included in the transistor, the overall threshold voltage of the transistor is reduced.

The energy band diagram of FIG. 4 corresponds to a transistor structure in which the gate conductor has been formed from a metal or other material that has a p-type characteristic. Region 158 corresponds to this gate conductor and is shown for illustrative purposes as having a Fermi level appropriate for p+ silicon. Region 160 corresponds to the gate insulator. Region 162 corresponds to p-type silicon in the transistor's body. Because the gate conductor's characteristic is “p-type,” and because the body region is p-type (in this example), there is minimal bending of the bands of region 162 in equilibrium, as shown in FIG. 4. Accordingly, transistor gate arrangements in which the gate conductor is formed from p+ semiconductor or a metal or other conductive material with an equivalent work function (e.g., a work function of 5.1 eV), tend to be characterized by conduction bands that are not lowered in the way that the conduction band in region 156 of FIG. 3 is lowered.

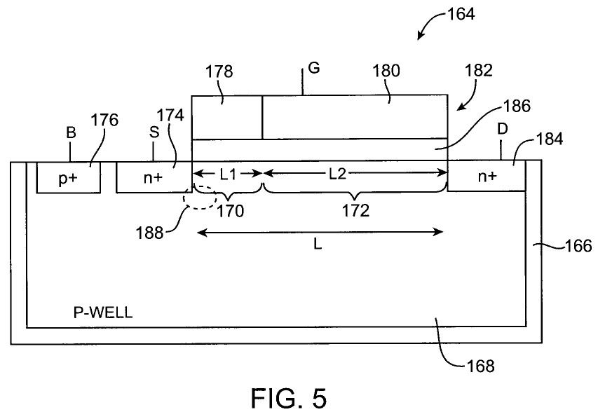

The relative behaviors of the first gate conductor of FIG. 3 and the second gate conductor of FIG. 4 can be used to create an energy band shape of the type shown in the graph of FIG. 2. Consider, as an example, the NMOS transistor arrangement of FIG. 5. As shown in FIG. 5, transistor 164 may be formed from a semiconductor substrate 166 such as a silicon substrate. Body region 168 may be doped with p-type dopant. Body contact region 176 may be formed from a p+ ion implantation region or other heavily doped p-type region. Source region 174 and drain region 184 may be formed from n+ ion implantation regions or other heavily doped n-type regions. Conductive gate structure 182 may have a first gate conductor 178 and a second gate conductor 180. Conductors 178 and 180 may be formed on gate insulating layer 186.

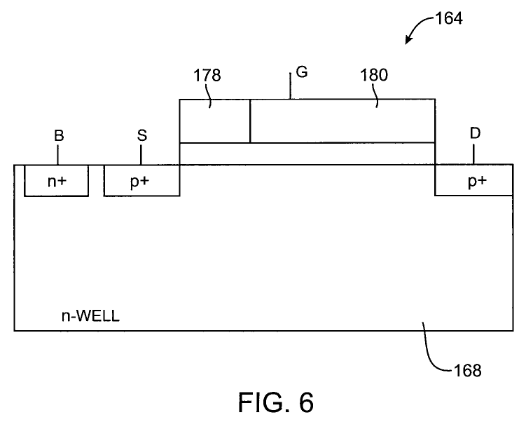

Gate insulating layer 186 may be formed from any suitable material such as silicon dioxide or high-K dielectric materials (i.e., dielectrics such as hafnium silicate, hafnium dioxide, zirconium silicate, and zirconium dioxide) that have a higher dielectric constant K than silicon dioxide. In transistor 164 FIG. 5, gate insulating layer 186 is formed on a semiconductor such as p-type silicon body region 168. In transistor 164 of FIG. 6, the gate insulating layer is formed on a semiconductor such as p-type silicon body 168. Typical gate conductor thicknesses are on the order of a thousand angstroms to several thousand angstroms. Typical gate insulator thicknesses are on the order of 40 angstroms (as an example). Larger or smaller film thicknesses may be used if desired.

The gate conductive layer of gate G in transistor 164 may be formed from multiple materials. Above channel region 170, gate conductor 178 may be formed from metal or other conductive materials having a p+ characteristic as described in connection with FIG. 4. These portions of the gate of transistor 164 will not lead to a lowered conduction band in well 168. Above channel region 172, gate conductor 180 may be formed from a metal or other conductive material having an n+ characteristic as described in connection with FIG. 3. This will lead to a lowered conduction band for region 172 of body 168, as in region CH of FIG. 2. Each gate conductor in the transistor gate may have a corresponding length. As shown in FIG. 5, gate conductor 178 may have a length L1 and gate conductor 180 may have a length L2.

On a given integrated circuit, the lengths L1 and L2 need not be the same for every transistor. Rather, different transistors may be fabricated with different ratios of L1/L2, thereby adjusting the threshold voltages for different transistors as appropriate for various circuit applications. These L1/L2 ratios can be selected manually or automatically by a computer-aided design tool during the design process so as to optimize overall circuit performance.

The energy band diagrams of FIGS. 3 and 4 are associated with gate conductors 180 and 178 in transistor 164 of FIG. 5. Region 158 in FIG. 4 corresponds to gate conductor 178 and may be formed from a material having a p+ semiconductor characteristic such as a metal or other conductive material with an equivalent work function (e.g., a work function of 5.1 eV). Region 150 in FIG. 3 corresponds to gate conductor 180 and may be formed from a material having an n+ semiconductor characteristic such as a metal or other conductive material with an equivalent work function (e.g., a work function of 4.2 eV).

The different materials in the gate structure 182 of transistor 164 are sometimes said to be arranged at different lateral locations along the channel of transistor 164, because each material lies adjacent to a different respective portion of the channel region. Gate conductor 178 is adjacent to body region 170, whereas gate conductor 180 is adjacent to body region 172. If desired, additional conductive materials may be included in gate structure 182. For example, a blanket layer of conductor (e.g., metal) may be formed that overlaps some or all of conductive structures 178 and 180.

The gate width of transistor 164 may be measured along the dimension perpendicular to length L (i.e., into the page of FIG. 5). Transistor 164 may have any suitable gate width. For example, transistor 164 may have a gate width that is larger than gate length L, that is more than two times the gate length L, that is more than three times the gate length L, etc. The length L may be equal to the sum of gate conductor lengths L1 and L2. Length L may be relatively short or may be longer (e.g., to form a so-called long-channel device). In a typical long-channel device arrangement, the length L may be two times larger, three times larger, four times larger, or more than two, three or four times larger than the minimum gate length Lmin that is permitted by semiconductor fabrication design rules.

When placed above body 168, region 178 leads to a larger conduction band height than when region 180 is placed above body 168, creating energy barrier 148 of FIG. 2. As described in connection with FIG. 2, energy barrier 148 may help to improve transistor performance. The lateral extent of energy barrier 148 and therefore the threshold voltage Vt of the transistor may be adjusted by adjusting the relative sizes of regions 178 and 180. Because energy barrier 148 may be produced by using gate conductors 178 and 180 with different work functions, it is not necessary to use a pocket implant in transistor 164. A source-side pocket implant may, nevertheless, be used in combination with the structure of FIG. 5, as indicated by optional p+ pocket implant region 188. Pocket implant region 188 may have a lower doping level than the doping levels used for conventional pocket implants such as doping concentrations less than 10¹⁷ cm⁻³, 10¹⁸ cm⁻³, etc.

As shown in FIG. 6, p-channel metal-oxide-semiconductor (PMOS) asymmetric transistors may be formed that have gates containing multiple gate conductors with different work functions.

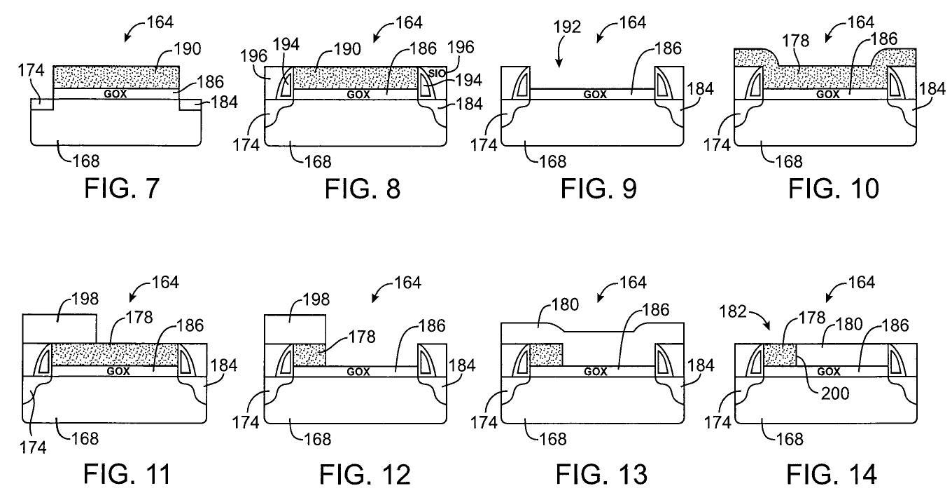

Illustrative techniques for use in forming transistors such as transistors 164 of FIGS. 5 and 6 are shown in FIGS. 7, 8, 9, 10, 11, 12, 13, and 14. These FIGS. present cross-sectional views of metal-oxide-semiconductor transistor structures with gates formed from two laterally spaced conductive materials during successive phases of fabrication. The fabrication process described in connection with FIGS. 7, 8, 9, 10, 11, 12, 13, and 14 uses a mask-based gate conductor formation technique in which a photolithographic mask is used to define the relative sizes of gate conductors 178 and 180 (i.e., lengths L1 and L2). This allows potentially large numbers of transistors on an integrated circuit to be constructed with individually tailored threshold voltages Vt. Because source-side pocket implants are optional, the use of additional mask layers for forming pocket-implant blocking structures during fabrication can be avoided.

In the partially formed transistor structure 164 of FIG. 7, gate insulating layer 186 (GOX) has been formed on silicon body region 168. Gate insulating layer 186 may be formed from silicon oxide or a high-K gate insulator (i.e., a gate insulator with a dielectric constant greater than the dielectric constant of silicon oxide). Sacrificial polysilicon gate structure 190 may be deposited and patterned on top of gate insulating layer 186. After structure 190 has been formed, the first of two source-drain ion implantation steps may be performed to begin forming source and drain regions 174 and 184. For example, a low density implant of the type that is sometimes referred to as a lightly doped drain implant may be made. During the lightly doped drain implant process, the sacrificial polysilicon layer 190 may serve as an implant mask that protects the channel region under gate insulating layer 186.

As shown in FIG. 8, spacers such as spacers 194 may be formed adjacent to polysilicon gate structure 190. The second of the two source-drain ion implantation steps may then be performed to finish the process of forming source region 174 and drain region 184. During the second ion implantation step, spacers 194 may serve as implant masks that ensure that the implant is spaced laterally away from the channel region under gate insulating layer 186.

After the second source-drain implant has been performed, a layer of silicon oxide 196 may be deposited. The transistor structure may then be polished to produce a planar upper surface as shown in FIG. 8.

As shown in FIG. 9, sacrificial polysilicon layer 190 may be removed to produce opening 192 above gate insulating layer 186. Any suitable polysilicon etching process may be used to remove polysilicon layer 190 (e.g., dry or wet etching, etc.).

Following polysilicon removal, a layer of metal for first metal gate 178 may be deposited, as shown in FIG. 10.

Following polishing (e.g., using chemical mechanical polishing techniques), photoresist layer 198 may be deposited and photolithographically patterned on top of the metal layer 178, as shown in FIG. 11.

Etching may then be used to remove the undesired portion of metal gate portion 178, as shown in FIG. 12. After etching is complete, photoresist 198 may be removed.

As shown in FIG. 13, a layer of metal for second gate conductor 180 may be deposited on top of the opening formed in the etching operations of FIG. 12. Following polishing, transistor 164 appears as shown in FIG. 14. As shown in FIG. 14, gate structure 182 of transistor 164 has first and second gate conductors 178 and 180 on gate insulating layer 186 formed from metals or other conductive materials having two different work functions. The gate conductors are arranged at different lateral locations along the surface of gate insulating layer 186 and are electrically connected at interface 200.

During fabrication, photolithographic masks may be used to define the shapes and sizes of transistor structures such as the shapes and sizes of gate conductors 178 and 180. In particular, a photolithographic mask may be used to define the extent to which patterned photoresist layer 198 of FIG. 11 overlaps layer 178 of FIG. 11 and thereby protects the overlapped portion of layer 178 during subsequent etching operations. In transistors in which the mask pattern specifies that a relatively large amount of layer 178 is to be protected, the resulting ratio of the length of gate conductor 178 (length L1 of FIG. 5) to the length of gate conductor 180 (length L2 of FIG. 5) will be large. In other transistors, the mask pattern may specify that a relatively smaller amount of layer 178 is to be protected. In these transistors, the ratio of the length of gate conductor 178 to the length of gate conductor 180 will be relatively small.

In a given transistor, the ratio of length L1 to L2 affects the threshold voltage of the transistor. For example, when L1/L2 is larger, the threshold voltage may be larger. Accordingly, the mask pattern that is used to form the gate conductors 1178 and 180 can be used to create individualized transistor threshold voltages for the transistors on an integrated circuit.

There may be numerous transistors such as transistor 164 on a given integrated circuit (e.g., millions of transistors 164). The threshold voltage of each transistor may be different or, if desired, groups of transistors may be fabricated each of which has a distinct threshold voltage. There may be, for example, two different groups, three different groups, four different groups, or more than four different groups of transistors on an integrated circuit, each group being characterized by a different gate conductor length ratio L1/L2 and corresponding threshold voltage.

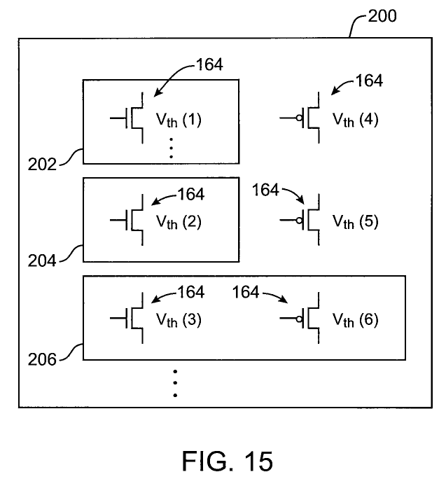

An illustrative integrated circuit 200 that includes mixed gate transistors 164 is shown in FIG. 15. As shown in FIG. 15, integrated circuit 200 may include numerous transistors 164. Various groups of transistors 164 may be formed, each of which has a different threshold voltage Vt determined by the sizes of the gate conductors within the transistors of that group. Transistors 164 may be fabricated so that the transistors that are part of particular circuit or that are needed to perform a particular type of function may have different threshold voltages than those that are in a different circuit or that are needed to perform a different type of function. For example, transistors that are required to exhibit particularly fast switching speeds may be provided with lower threshold voltages, whereas transistors for which low power consumption is desirable and for which switching speed is less critical may be provided with higher threshold voltages. These threshold voltage assignments may be made manually or automatically using a circuit design system.

In the FIG. 15 example, circuits such as circuits 202, 204, and 206 in integrated circuit 200 each have numerous transistors 164 with different threshold voltages Vt. During fabrication, the photolithographic mask that is used in patterning the gate conductors sizes for transistors 164 can be used in fabricating appropriate gate conductors for each of these transistors 164 in parallel. During operation of integrated circuit 200, the individualized transistor threshold voltages may enhance the performance of circuit 200 by ensuring that each transistor performs its intended function using an optimal threshold voltage.

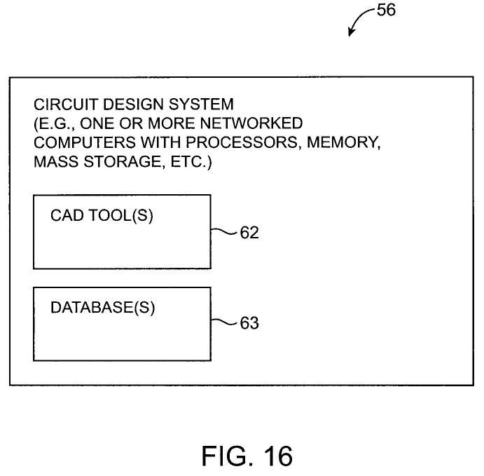

There are typically many transistors on a given integrated circuit. Some or all of these transistors may be fabricated using mixed gate arrangements. Circuit design systems based on computer-aided design tools may be used to assist circuit designers in the design and fabrication of integrated circuits with mixed gate transistors. An illustrative circuit design system 56 that may be used in designing mixed gate transistors is shown in FIG. 16.

Logic design system 56 of FIG. 16 can help a circuit designer design and test complex circuits for a system such as circuits that include mixed gate transistors such as transistors 164. When a design is complete, the logic design system may be used to generate and store mask designs for photolithographic masks for a corresponding integrated circuit. The photolithographic masks may be used in fabricating the integrated circuit.

Logic circuit design system 56 may be based on one or more computers and their associated storage hardware and may therefore include processing circuitry and storage. In supporting design operations involved in implementing a desired circuit function, software runs on the processing circuitry and storage of system 56 and is used in making design decisions such as the sizes and shapes of gate conductor structures, the sizes and shapes of other device features, interconnect and layout patterns for masks, etc.

Any suitable hardware may be used in implementing system 56. For example, system 56 may be based on one or more processors such as personal computers, workstations, etc. The processor(s) may be linked using a network (e.g., a local or wide area network). Memory in these computers or external memory and storage devices such as internal and/or external hard disks may be used to store instructions and data.

Software-based components such as computer-aided design tools 62 and databases 63 reside on system 56. During operation, executable software such as the software of computer aided design tools 62 runs on the processor(s) of system 56. Databases 63 are used to store circuit design data, mask design data, and other data for the operation of system 56. In general, software and data may be stored on any computer-readable medium (storage) in system 56. Such storage may include computer memory chips, removable and fixed media such as hard disk drives, flash memory, compact discs (CDs), DVDs, other optical media, and floppy diskettes, tapes, or any other suitable memory or storage device(s). When the software of system 56 is installed, the storage of system 56 has instructions and data that cause the computing equipment in system 56 to execute various methods (processes). When performing these processes, the computing equipment is configured to implement the functions of the circuit design system.

The computer aided design (CAD) tools 62, some or all of which are sometimes referred to collectively as a CAD tool, may be provided by a single vendor or multiple vendors. Tools 62 may be provided as one or more suites of tools and/or as one or more separate software components (tools). Database(s) 63 may include one or more databases that are accessed only by a particular tool or tools and may include one or more shared databases. Shared databases may be accessed by multiple tools. For example, a first tool may store data for a second tool in a shared database. The second tool can access the shared database to retrieve the data stored by the first tool. This allows one tool to pass information to another tool. Tools may also pass information between each other without storing information in a shared database if desired.

When a circuit designer uses tools 62 to implement a circuit, the circuit designer is faced with a number of potentially challenging design decisions. The designer must balance factors such as cost, size, and performance to create a workable end product. Tradeoffs are involved. For example, a circuit of a given design can be implemented so that it operates quickly, but consumes a large amount of power and on-chip resources or can be implemented so that is operates more slowly, while consuming less power and fewer resources.

When balancing factors such as these, a circuit designer can use CAD tools 62 to manually and automatically produce gate conductors 178 and 180 for various transistors 164 that tailor the threshold voltage Vt of those transistors as needed. Lower threshold voltages may be used in those portions of a circuit where speed is paramount, whereas higher threshold voltages may be used to conserve power where possible.

A circuit designer can use tools 62 to manually and automatically make design decisions that allow optimum selection of threshold voltages for the transistors to be made, while satisfying design constraints such as timing margins, power consumption, area consumption, etc. For clarity, threshold voltage optimization functions and other design functions are sometimes described herein in the context of logic design system 56 and CAD tools 62. In general, any suitable number of software components (e.g., one or more tools) may be used to provide a circuit designer with design assistance for mixed gate transistor circuits. These software components may be separate from logic design tools, mask layout tools and other software in tools 62 or some or all of the software components that provide circuit design assistance functionality may be provided within logic synthesis and optimization tools, a layout tool, etc.

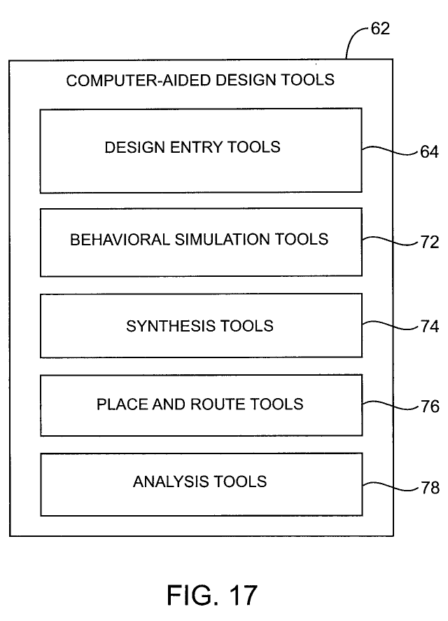

Illustrative computer aided design tools 62 that may be used in a circuit design system such as system 56 of FIG. 16 are shown in FIG. 17.

The design process typically starts with the formulation of circuit functional specifications. A circuit designer can specify how a desired circuit should function using design entry tools 64. Design entry tools 64 may include tools such as design and constraint entry aids and design editors. Design entry aids may be used to help a circuit designer locate a desired design from a library of existing designs and may provide computer-aided assistance to the designer when entering a desired design. For example, a design entry aid may be used to present screens of options for a user. The user may click on on-screen options to select whether the circuit being designed should have certain features. Design editors may be used to enter a design (e.g., by entering lines of hardware description language code), may be used to edit a design obtained from a library (e.g., using a design entry aid), or may assist a user in selecting and editing appropriate prepackaged code/designs.

Design entry tools 64 may be used to allow a circuit designer to provide a desired circuit design using any suitable format. For example, design entry tools 64 may include tools that allow the circuit designer to enter a logic design using truth tables. Truth tables can be specified using text files or timing diagrams and may be imported from a library. Truth table logic design and constraint entry may be used for a portion of a large circuit or for an entire circuit.

As another example, design entry tools 64 may include a schematic capture tool. A schematic capture tool may allow the logic designer to visually construct logic circuits from constituent parts such as logic gates and groups of logic gates. Libraries of preexisting analog and digital circuits may be used to allow a desired portion of a design to be imported with the schematic capture tools.

If desired, design entry tools 64 may allow the circuit designer to provide a circuit design to the circuit design system 56 using a hardware description language (e.g., as a register transfer level design). The designer of the circuit can enter the design by writing hardware description language code with an editor. Blocks of code may be imported from user-maintained or commercial libraries.

After the design has been entered using design entry tools 64, behavioral simulation tools 72 may be used to simulate the functional performance of the design. If the functional performance of the design is incomplete or incorrect, the designer can make changes to the design using design and constraint entry tools 64. The functional operation of the new design can be verified using behavioral simulation tools 72 before synthesis operations have been performed using tools 74. Simulation tools such as tools 72 may also be used at other stages in the design flow if desired (e.g., after logic synthesis). The output of the behavioral simulation tools 72 may be provided to the circuit designer in any suitable format (e.g., truth tables, timing diagrams, etc.).

Once the functional operation of the circuit design has been determined to be satisfactory, synthesis tools 74 may be used to implement the design in a particular device technology (i.e., in a particular set of available transistors 164 and associated circuits). For example, system 56 may maintain a list of various predefined transistors 164 in database 63, each of which has a particular threshold voltage Vt determined by its L1/L2 ratio. During use of synthesis tools 74, appropriate transistors 164 can be selected from this pool of predefined structures. Tools 74 or other tools 62 may also be used in manually and automatically designing transistors 164 with appropriate L1/L2 ratios.

Tools 74 may be used in optimization operations. For example, tools such as tools 74 may be used to optimize a design by making appropriate selections of hardware to implement different logic functions in the circuit design based on the circuit design data and constraint data entered by the circuit designer using tools 64.

After synthesis and optimization using tools 74, the circuit designer may use tools such as place and route tools 76 to perform physical design steps (layout synthesis operations). Place and route tools 76 may be used to help determine how to optimally place the circuits for various functions within an integrated circuit die. If desired, a designer may provide guidance (e.g., to determine an optimum “floorplan” for a chip). Place and route tools 76 preferably help create orderly and efficient implementations of circuit designs for a given integrated circuit.

Tools such as tools 74 and 76 may be part of a suite of tools. If desired, tools such as tools 74 and 76 may manually and automatically take into account the effects of using different gate conductor lengths (L1 and L2) within mixed gate transistors to adjust their threshold voltages while implementing a desired circuit design. This allows tools 74 and 76 to minimize power consumption (e.g., power consumption due to pass transistor leakage currents) while satisfying design constraints such as timing constraints.

After place and route tools have generated a layout for the circuit design, the design may be analyzed and tested using analysis tools 78. After satisfactory optimization operations have been completed using tools 62, tools 62 can produce and store layout data for generating mask sets for fabricating integrated circuits with the desired design.

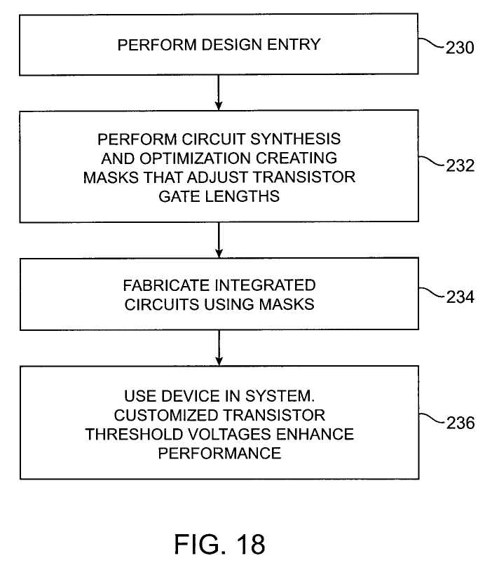

Illustrative operations involved in producing integrated circuits having mixed gate transistors with various threshold voltages are shown in FIG. 18.

At step 230, tools such as design entry tools 64 may use input screens to obtain a desired circuit design from a circuit designer. The design may include design constraints such as timing constraints, signal strength constraints, logic function constraints, etc. Settings screens and other suitable user input arrangements may be used to gather settings related to choosing appropriate L1/L2 ratios for mixed gate transistors. If desired, some or all settings may be provided as defaults. User input arrangements such as these may also be used to obtain other design constraints, etc. For example, a circuit designer can specify constraints such as delay or speed limits, desired power supply voltages, current drive limits, noise level limits, logic voltage settings, I/O circuit voltage settings, power consumption levels, etc. A circuit designer may, as an example, specify that a particular circuit path should operate at a particular minimum speed. If desired, settings such as these may be provided as defaults (e.g., when a designer does not specify any such constraints).

At step 232, logic synthesis and optimization, physical design, and timing simulation operations may be performed using tools 72, 74, 76, and 78. During these operations, CAD tools 62 may process the design constraints and obtained at step 230 to produce a mask design for photolithographic masks that can be used to fabricate the desired integrated circuit and appropriately configured mixed gate transistors with that integrated circuit. The design can be stored in storage such as storage 63 of FIG. 16. The masks can then be fabricated (e.g., by retrieving the stored data using a mask fabrication tool and performing e-beam lithography and other suitable fabrication operations to produce the masks). During step 232, the CAD tools identify appropriate ratios of gate lengths L1/L2 that will allow the circuitry in the integrated circuit to meet timing constraints and other constraints without consuming excessive amounts of power (e.g., by choosing optimal threshold voltages for transistors 164 and adjusting the L1/L2 ratio for those transistors accordingly so that power consumption is minimized while timing constraints are satisfied). These operations may be performed based on the user-supplied settings gathered during step 230.

At step 234, integrated circuits can be fabricated using the masks that are generated at step 232. The integrated circuits will generally contain some transistors that do not have mixed gates and some transistors that contain mixed gates. The mixed gate transistors may have asymmetric configurations that exhibit increased output resistance and enhanced gain relative to conventional transistors of the same size. This allows the mixed gate transistors to be used for applications such as analog circuits. Among the mixed gate transistors, the threshold voltage of each transistor may be such that the overall performance of the integrated circuit is optimized.

At step 236, an integrated circuit device that has been fabricated during step 234 may be used in a system. For example, the integrated circuit may be mounted on a printed circuit board and used in conjunction with other integrated circuits to perform suitable functions.

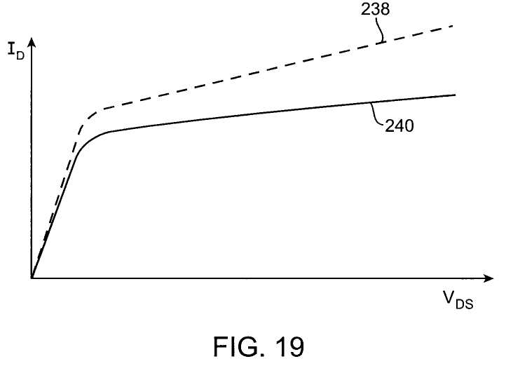

FIG. 19 is a graph showing how output resistance Rout varies inversely with the slope of a transistors drain current (Id) versus drain-source voltage (Vds) characteristic. Output resistance Rout is a measure of the impact of drain source voltage on drain current. For applications such as analog circuits in which high gain is desired, it is particularly beneficial for the value of Rout to be high, so that its reciprocal (1/Rout) is low.

The graph of FIG. 19 shows expected performance improvements when using mixed gate transistors such as transistors 164 of FIGS. 5 and 6 in place of comparably sized conventional transistors. Curve 238 of FIG. 19 corresponds to a conventional metal-oxide-semiconductor transistor, with a relatively low Rout value, leading to a relatively steep curve slope. Curve 240 of FIG. 19 corresponds to an asymmetric mixed gate transistors 164 of the same size and shape as the conventional transistor. Because of mixed gate of the asymmetric transistor, output resistance is increased for the same gate size. This leads to a relatively high Rout value and a curve slope for curve 240 that is shallower than the curve slope 238 of the conventional transistor.

The foregoing is merely illustrative of the principles of this invention and various modifications can be made by those skilled in the art without departing from the scope and spirit of the invention.

What is claimed is:

1. A transistor comprising:
a semiconductor;
a high-K gate insulating layer on the semiconductor; and
first and second gate conductors formed on the gate insulating layer.

2. The transistor defined in claim 1 wherein the first gate conductor comprises a conductive material with a first work function and the second gate conductor comprises a conductive material with a second work function that is different than the first work function, so that the transistor exhibits a larger output resistance than a transistor of equal size without a mixed gate.

3. The transistor defined in claim 1 wherein the first gate conductor and second gate conductor are different metals with different respective work functions.

4. The transistor defined in claim 1 wherein the gate insulating layer comprises a dielectric selected from the group consisting of: hafnium silicate, hafnium dioxide, zirconium silicate, and zirconium dioxide.

5. The transistor defined in claim 4 wherein the first gate conductor and second gate conductor are different metals.

6. The transistor defined in claim 5 further comprising a source region and a drain region in the semiconductor that are adjacent to the gate insulating layer and that define a gate length for the transistor, wherein semiconductor design rules used in forming the transistor specify a minimum gate length and wherein the gate length for the transistor is at least three times the minimum gate length.

7. The transistor defined in claim 1 further comprising a source region and a drain region in the semiconductor that are adjacent to the gate insulating layer and that define a gate length for the transistor, wherein the transistor is fabricated with a semiconductor fabrication process that has a design rule specifying a minimum gate length and wherein the gate length is more than two times the minimum gate length.

8. An integrated circuit comprising:
a first transistor; and
a second transistor, wherein the first transistor and the second transistor each have a gate with two gate conductors of different work functions and respective first and second gate conductor lengths, wherein the gate of the first transistor and the gate of the second transistor have equal lengths, and wherein the first gate conductor length in the first transistor is different than the first gate conductor length in the second transistor.

9. The integrated circuit defined in claim 8 further comprising a source-side pocket implant in the first transistor.

10. The integrated circuit defined in claim 8 further comprising:
a third transistor having a gate of length equal to the length of the gate in the first transistor, wherein the third transistor has first and second gate conductors with respective first and second gate conductor lengths, and wherein the first gate conductor length in the third transistor is different than the first gate conductor length in the first transistor and is different than the first gate conductor length in the second transistor.

11. The integrated circuit defined in claim 10 wherein the first and second gate conductors in the first transistor are different metals, wherein the first and second gate conductors in the second transistor are different metals, and wherein the first and second gate conductors in the third transistor are different metals.

12. The integrated circuit defined in claim 11 wherein the first, second, and third transistors each have a respective gate insulating layer formed from a dielectric selected from the group consisting of: hafnium silicate, hafnium dioxide, zirconium silicate, and zirconium dioxide.

13. The integrated circuit defined in claim 8 wherein the first and second transistors each have a respective gate insulating layer formed from a dielectric selected from the group consisting of: hafnium silicate, hafnium dioxide, zirconium silicate, and zirconium dioxide.

14. The integrated circuit defined in claim 13 wherein the first and second gate conductors in the first and second transistors are formed from metal.

15. The integrated circuit defined in claim 8 wherein the first transistor has a gate insulating layer, wherein silicon oxide has a dielectric constant, wherein the gate insulating layer has a dielectric constant greater than silicon oxide, and wherein the gate of the first transistor has a width greater than its length.

16. The integrated circuit defined in claim 15 further comprising a plurality of transistors that have gates of a minimum gate length permitted by semiconductor fabrication design rules, and wherein the first and second transistors each have an associated gate length that is at least three times the minimum gate length.

17. The integrated circuit defined in claim 15 wherein the first and second gate conductors in the first and second transistors are formed from metal.

18. The integrated circuit defined in claim 17 further comprising a plurality of transistors that have gates of a minimum gate length permitted by semiconductor fabrication design rules, and wherein the first and second transistors each have an associated gate length that is at least three times the minimum gate length.

19. A method for using a circuit design system in designing an integrated circuit that contains a plurality of mixed gate metal-oxide-semiconductor transistors each having an associated pair of gate conductors with respective gate conductor lengths and an associated gate conductor length ratio, comprising:
using the circuit design system to allow a circuit designer to specify a desired circuit design; and
generating and storing a mask design for photolithographic masks in which the gate conductor length ratios are different for at least some of the mixed gate transistors.

20. The method defined in claim 19 wherein generating and storing the mask design comprises determining which portions of the desired circuit design include a first group of the mixed gate transistors with a first threshold voltage and which portions of the desired circuit design include a second group of the mixed gate transistors with a second threshold voltage that is different than the first threshold voltage.
